(19) United States
(12) Patent Application Publication
(10) Pub. No.: US 2025/0133871 A1
(43) Pub. Date: Apr. 24, 2025

(54) DISPLAY DEVICE AND METHOD FOR MANUFACTURING THE SAME

(71) Applicant: Samsung Display Co., Ltd., Yongin-si (KR)

(72) Inventors: YUK-HYUN NAM, Yongin-si (KR); YOOLGUK KIM, Yongin-si (KR); HYEONSIK KIM, Yongin-si (KR); HEEWOON IM, Yongin-si (KR)

(73) Assignee: Samsung Display Co., Ltd., Yongin-si (KR)

(21) Appl. No.: 18/768,890

(22) Filed: Jul. 10, 2024

(30) Foreign Application Priority Data
Oct. 23, 2023 (KR) 10-2023-0142268

(51) Int. Cl. H01L 33/06; H01L 25/075

(52) U.S. Cl. CPC H10H 20/812; H01L 25/0753; H10H 20/036

(57) ABSTRACT

A display device includes a base layer, an insulating layer disposed on the base layer, a pixel defining film disposed on the insulating layer and having a pixel opening, a light-emitting element disposed on the insulating layer, and an inorganic layer disposed on the insulating layer and including an edge disposed more inward than an edge of the pixel defining film. The light-emitting element includes a first electrode, a second electrode, a light-emitting layer including quantum dots and disposed between the first electrode and the second electrode, a hole transport region, and an electron transport region including a metal oxide, spaced apart from the hole transport region, and disposed between the first electrode and the second electrode.

### CROSS-REFERENCE TO RELATED APPLICATION(S)

This application claims priority to and benefits of Korean Patent Application No. 10-2023-0142268 under 35 U.S.C. § 119, filed on Oct. 23, 2023, in the Korean Intellectual Property Office (KIPO), the entire contents of which are incorporated herein by reference.

### BACKGROUND

### 1. Technical Field

The disclosure herein relates to a display device including a quantum dot light-emitting element and a method of manufacturing the same.

### 2. Description of the Related Art

A light-emitting element has the property of converting electrical energy into light energy. Among light-emitting elements, a quantum dot light-emitting element containing quantum dots in a light-emitting layer has high color purity and high light-emitting efficiency and can display multi color. In the light-emitting element, holes move to the light-emitting layer via a hole transport region, and electrons move to the light-emitting layer via an electron transport region. Research is being conducted on efficient injection and transport of electrons in order to improve light efficiency in the quantum dot light-emitting element.

### SUMMARY

The disclosure provides a display device that exhibits excellent display efficiency.

The disclosure also provides a method for manufacturing a display device, the method exhibiting excellent manufacturing efficiency.

According to an embodiment of the disclosure, a display device may include a base layer, an insulating layer disposed on the base layer, a pixel defining film disposed on the insulating layer and having a pixel opening, a light-emitting element disposed on the insulating layer, and an inorganic layer disposed on the insulating layer and including an edge which is disposed more inward than an edge of the pixel defining film and overlaps the pixel defining film in a plan view. The light-emitting element may include a first electrode exposed by the pixel opening, a second electrode disposed on the first electrode, a light-emitting layer including quantum dots and disposed between the first electrode and the second electrode, a hole transport region disposed between the first electrode and the second electrode, and an electron transport region including a metal oxide, spaced apart from the hole transport region with the light-emitting layer interposed between the electron transport region and the hole transport region, and disposed between the first electrode and the second electrode.

In an embodiment, the inorganic layer may include at least one of amorphous silicon, silicon nitride, silicon oxide, and silicon oxynitride.

In an embodiment, in a direction perpendicular to a thickness direction of the display device, the inorganic layer may be in contact with the electron transport region.

In an embodiment, the inorganic layer may not overlap the pixel opening in a plan view.

In an embodiment, the inorganic layer may cover an edge of the first electrode.

In an embodiment, the inorganic layer may be in contact with the insulating layer.

In an embodiment, an inorganic opening may be defined in the inorganic layer, and the inorganic opening may overlap the pixel opening in a plan view.

In an embodiment, the first electrode may be spaced apart from the pixel defining film with the inorganic layer interposed between the first electrode and the pixel defining film.

In an embodiment, the pixel defining film may be spaced apart from the insulating layer with the inorganic layer interposed between the pixel defining film and the insulating layer.

In an embodiment, the insulating layer may include a first region that overlaps the pixel defining film in a plan view and has a first thickness, and a second region that overlaps the pixel opening in a plan view and has a second thickness smaller than the first thickness.

In an embodiment, the inorganic layer may entirely overlap the first region in a plan view.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, or TiO₂, and a compound represented by Formula M-1 below.

Zn_{q}Me_{(1-q)}O [Formula M-1]

In an embodiment, in Formula M-1, q may be a rational number between 0 and 0.5, and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

According to an embodiment of the disclosure, a method for manufacturing a display device may include preparing a base layer; forming an insulating layer on the base layer; forming a first electrode on the insulating layer; forming a preliminary inorganic layer on the first electrode; forming a preliminary pixel defining film on the preliminary inorganic layer by using a first halftone mask; forming an inorganic layer and a pixel defining film having a pixel opening by removing a first portion of the preliminary inorganic layer and a second portion of the preliminary pixel defining film overlapping the first portion in a plan view; forming a functional layer on the first electrode exposed by the pixel opening; and forming a second electrode on the functional layer. The forming of the functional layer may include forming a light-emitting layer by providing a first composition including quantum dots; forming a hole transport region; and forming an electron transport region by providing a second composition including a metal oxide. One of the forming of the hole transport region and the forming of the electron transport region may be performed before the forming of the light-emitting layer, and another one of the forming of the hole transport region and the forming of the electron transport region may be performed after the forming of the light-emitting layer.

In an embodiment, in the forming of the inorganic layer and the pixel defining film, an edge of the inorganic layer may be disposed more inward than an edge of the pixel defining film.

In an embodiment, the first portion of the preliminary inorganic layer and the second portion of the preliminary pixel defining film may be removed through an ashing process.

In an embodiment, the insulating layer may be formed to include a first region having a first thickness and a second region having a second thickness smaller than the first thickness by using a second halftone mask.

In an embodiment, each of the first portion of the preliminary inorganic layer and the second portion of the preliminary pixel defining film may overlap the second region of the insulating layer in a plan view.

In an embodiment, the inorganic layer may include at least one of amorphous silicon, silicon nitride, silicon oxide, and silicon oxynitride.

In an embodiment, each of the first composition and the second composition may be provided by an inkjet printing method or a dispensing method.

In an embodiment, the method of manufacturing the display device may further include performing plasma treatment by providing a fluorine-containing gas to the pixel defining film before the forming of the light-emitting layer, the hole transport region, and the electron transport region. The fluorine-containing gas may include at least one of CF₄, C₃F₆, C₄F₈, SF₆, CHF₃, C₅F₈, CH₂F₂, C₂HF₅, CH₃F, and NF₃.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view illustrating a display device according to an embodiment of the disclosure;

FIG. 2 is a schematic cross-sectional view illustrating a portion corresponding to line I-I′ in FIG. 1;

FIG. 3 is a plan view illustrating the display device according to an embodiment of the disclosure;

FIG. 4 is a schematic cross-sectional view illustrating a portion corresponding to line II-II′ in FIG. 3;

FIG. 5A is an enlarged schematic cross-sectional view of region AA′ in FIG. 4;

FIG. 5B is a schematic cross-sectional view illustrating a portion of the display device according to an embodiment of the disclosure;

FIG. 6 is an enlarged schematic cross-sectional view of region BB′ in FIG. 4;

FIG. 7 is a schematic cross-sectional view illustrating a display device according to an embodiment of the disclosure;

FIG. 8 is a flowchart showing a method of manufacturing a display device according to an embodiment of the disclosure;

FIG. 9A is a flowchart showing some of the method of manufacturing the display device according to an embodiment of the disclosure;

FIG. 9B is a flowchart showing some of the method of manufacturing the display device according to an embodiment of the disclosure;

FIG. 10 schematically illustrates a step of manufacturing the display device according to an embodiment of the disclosure;

FIG. 11 schematically illustrates a step of manufacturing the display device according to an embodiment of the disclosure;

FIG. 12 schematically illustrates a step of manufacturing the display device according to an embodiment of the disclosure;

FIG. 13 schematically illustrates a step of manufacturing the display device according to an embodiment of the disclosure;

FIG. 14 schematically illustrates a step of manufacturing the display device according to an embodiment of the disclosure;

FIG. 15 schematically illustrates a step of manufacturing the display device according to an embodiment of the disclosure;

FIG. 16 schematically illustrates a step of manufacturing the display device according to an embodiment of the disclosure;

FIG. 17 schematically illustrates a step of manufacturing the display device according to an embodiment of the disclosure; and

FIG. 18 schematically illustrates a step of manufacturing the display device according to an embodiment of the disclosure.

### DETAILED DESCRIPTION OF THE EMBODIMENTS

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element. The terms of a singular form include plural forms unless otherwise specified.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

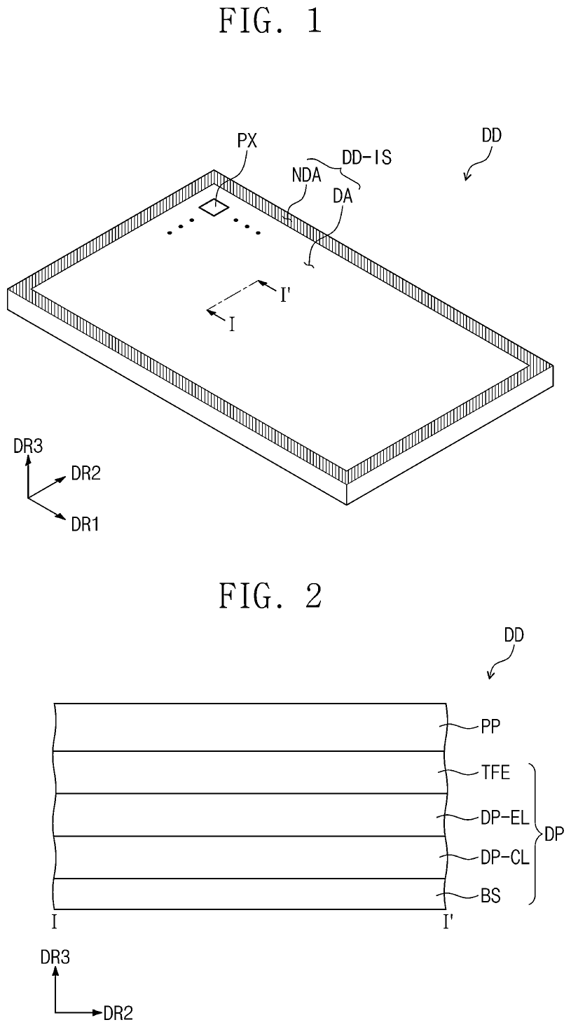

Hereinafter, a display device according to an embodiment of the disclosure will be described with reference to the accompanying drawings. FIG. 1 is a perspective view illustrating a display device according to an embodiment of the disclosure.

Referring to FIG. 1, the display device DD according to an embodiment of the disclosure may be activated according to an electrical signal. For example, the display device DD may be a large-sized device such as a television, a monitor, or an external billboard. The display device DD may be a small or medium-sized device such as a personal computer, a laptop computer, a personal digital terminal, an automobile navigation unit, a game console, a smartphone, a tablet, or a camera. However, the disclosure is not limited thereto, and the display device DD may be applied to other types of display devices without departing from the concept of the disclosure.

The display device DD may display an image (or video image) through a display surface DD-IS. The display surface DD-IS may be parallel to a plane defined by first and second directions DR1 and DR2. The display surface DD-IS may include a display region DA and a non-display region NDA.

A pixel PX may be disposed in the display region DA and may not be disposed in the non-display region NDA. The non-display region NDA may be defined along an edge of the display surface DD-IS. The non-display region NDA may surround the display region DA in a plan view. However, the disclosure is not limited thereto, and the non-display region NDA may be omitted, or the non-display region NDA may be disposed only on a side of the display region DA.

Although FIG. 1 illustrates a display device DD having a flat display surface DD-IS, the disclosure is not limited thereto. The display device DD may include a curved display surface or a three-dimensional display surface. The three-dimensional display surface may include multiple display regions that face directions different from each other.

FIG. 1 and the following drawings illustrate a first direction axis DR1 to a third direction axis DR3, and the first to third direction axes DR1, DR2 and DR3 described herein are relative concepts and therefore may be converted into other directions. Directions indicated by the first to third direction axes DR1, DR2, and DR3 may be described as first to third directions, and the same reference numerals may be used for the directions. In this specification, the first direction axis DR1 and the second direction axis DR2 may be perpendicular to each other, and the third direction axis DR3 may be a direction normal to a plane defined by the first direction axis DR1 and the second direction axis DR2.

In this specification, a plane refers to the plane defined by the first direction axis DR1 and the second direction axis DR2, and a cross section refers to a plane perpendicular to the plane defined by the first direction axis DR1 and the second direction axis DR2 and parallel to the third direction axis DR3. The thickness direction of the display device DD may be parallel to the third direction DR3 which is a direction normal to the plane defined by the first direction DR1 and the second direction DR2.

In this specification, the upper (or front) and lower (or rear) surfaces of members constituting the display device DD may be defined based on the third direction DR3. For example, a surface relatively adjacent to the display surface DD-IS among two surfaces facing each other based on the third direction DR3 of one member may be defined as a front surface (or upper surface), and a surface spaced apart from the display surface DD-IS with the front surface (or upper surface) interposed between the surface and the display surface DD-IS may be defined as a rear surface (or lower surface). In this specification, upper and lower portions (or sides) may be defined based on the third direction DR3, and the upper portion (or upper side) may be defined in a direction towards the display surface DD-IS and the lower portion (or lower side) may be defined in a direction away from the display surface DD-IS.

In this specification, an expression “A component is ‘directly disposed/directly formed’ on another component” means that a third component is not disposed between them. The expression “A component is ‘directly disposed/directly formed’ on another component” means that a component is in contact with another component.

FIG. 2 is a schematic cross-sectional view illustrating a portion corresponding to line I-I′ of FIG. 1. FIG. 2 may be a schematic cross-sectional view of the display device DD according to an embodiment of the disclosure.

The display device DD may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

The display panel DP may be configured to generate an image. The display panel DP may be a light-emitting display panel. For example, the display panel DP may be a quantum dot light-emitting display panel including a quantum dot light-emitting element.

The base layer BS may be a member that provides a base surface on which the circuit layer DP-CL is disposed. The base layer BS may be a rigid substrate or a flexible substrate capable of being bent, folded, or rolled. The base layer BS may be a glass substrate, a metal substrate, a polymer substrate, or the like. However, the disclosure is not limited thereto, and the base layer BS may be an inorganic base layer, an organic base layer, or a composite material base layer.

The circuit layer DP-CL may be disposed on the base layer BS. The circuit layer DP-CL may include an insulating layer, a semiconductor pattern, a conductive pattern, and a signal line. An insulating layer, a semiconductor layer, and a conductive layer may be formed on the base layer BS by coating, deposition, or the like, and the insulating layer, the semiconductor layer, and the conductive layer may be selectively patterned through multiple photolithography processes. Accordingly, a semiconductor pattern, a conductive pattern, and a signal line included in the circuit layer DP-CL may be formed.

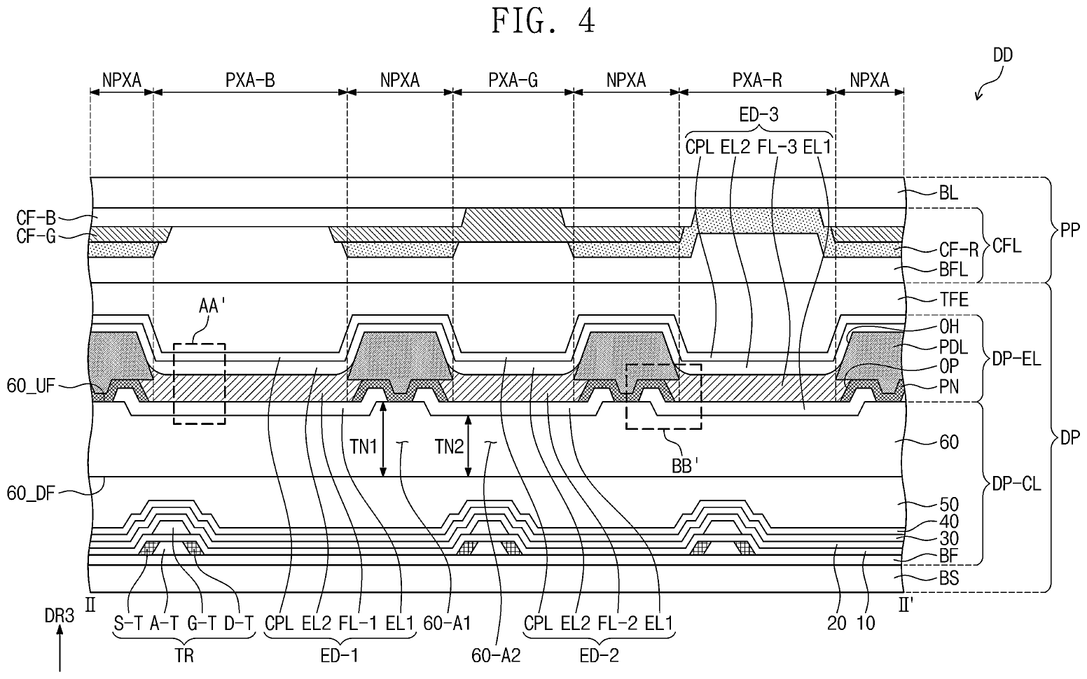

The display element layer DP-EL may be disposed on the circuit layer DP-CL. The display element layer DP-EL may include a pixel defining film PDL (see FIG. 4), which will be described below, and first to third light-emitting elements ED-1, ED-2, and ED-3 (see FIG. 4). For example, the display element layer DP-EL may include an organic light-emitting material, an inorganic light-emitting material, an organic-inorganic light-emitting material, a quantum dot, a quantum rod, a micro LED, or a nano LED. In an embodiment of the disclosure, the display element layer DP-EL may include quantum dots.

The encapsulation layer TFE may protect the display element layer DP-EL from moisture, oxygen, and foreign substances such as dust particles. The encapsulation layer TFE may include at least one inorganic film. The encapsulation layer TFE may include a structure in which an inorganic film, an organic film, and an inorganic film are sequentially stacked.

The optical layer PP may be disposed on the display panel DP and control light reflected from the display panel DP by external light. The optical layer PP may include, for example, a polarizing layer or a color filter layer. Unlike what is illustrated in the drawing, the optical layer PP may be omitted.

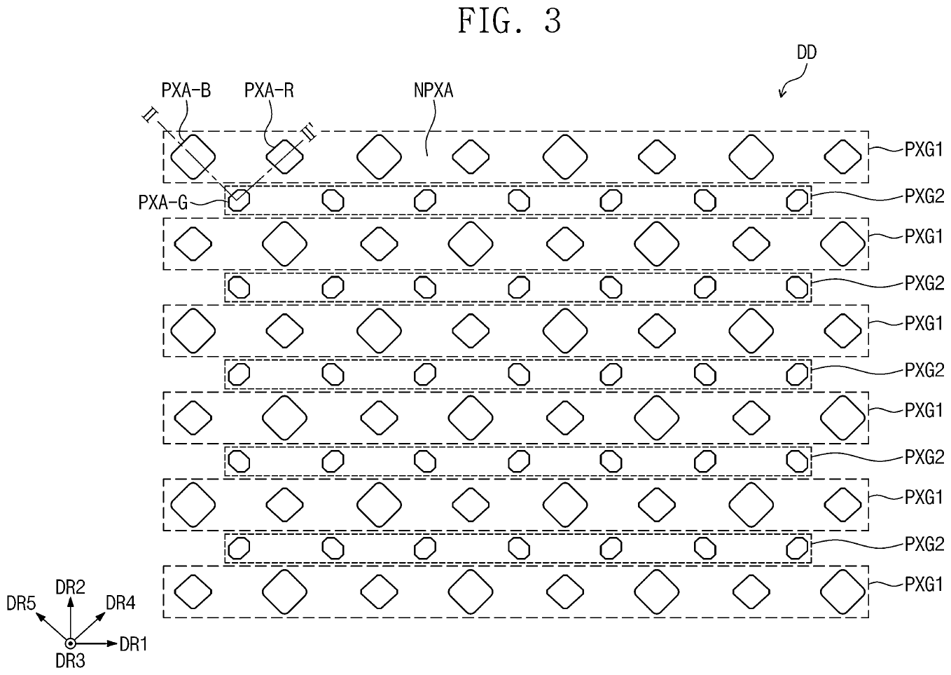

FIG. 3 is a plan view illustrating the display device DD according to an embodiment of the disclosure. FIG. 4 is a schematic cross-sectional view illustrating a portion corresponding to line II-II′ in FIG. 3. FIG. 3 may be a plan view illustrating the display region DA (see FIG. 1) of the display device DD. FIG. 4 may be a schematic cross-sectional view illustrating the display device DD according to an embodiment of the disclosure.

Referring to FIGS. 3 and 4, the display device DD may include a peripheral region NPXA and light-emitting regions PXA-B, PXA-G, and PXA-R. The light-emitting regions PXA-B, PXA-G, and PXA-R may be regions from which light generated from the light-emitting elements ED-1, ED-2, and ED-3 is emitted. The areas of the light-emitting regions PXA-B, PXA-G, and PXA-R may be different from each other, and the area may mean an area in a plan view.

The light-emitting regions PXA-B, PXA-G, and PXA-R may be divided into multiple groups according to the colors of light generated from the light-emitting elements ED-1, ED-2, and ED-3. FIGS. 3 and 4 schematically illustrate three light-emitting regions PXA-B, PXA-G, and PXA-R that emit blue light, green light, and red light according to an embodiment. For example, the display device DD according to an embodiment of the disclosure may include a blue light-emitting region PXA-B, a green light-emitting region PXA-G, and a red light-emitting region PXA-R that are separated from each other.

The display panel DP may include multiple light-emitting elements ED-1, ED-2, and ED-3 that emit light in different wavelength ranges. The light-emitting elements ED-1, ED-2, and ED-3 may emit light of different colors. For example, the display panel DP may include a first light-emitting element ED-1 that emits blue light, a second light-emitting element ED-2 that emits green light, and a third light-emitting element ED-3 that emits red light. However, the disclosure is not limited thereto, and the first to third light-emitting elements ED-1, ED-2, and ED-3 may emit light in a same wavelength range, or at least one of the first to third light-emitting elements ED-1, ED-2, and ED-3 may emit light in a wavelength range different from the others.

In the display device DD according to an embodiment of the disclosure, which is illustrated in FIGS. 3 and 4, the light-emitting regions PXA-B, PXA-G, and PXA-R may have different areas depending on the colors of light emitted from light-emitting layers EML-B, EML-G, and EML-R of the light-emitting elements ED-1, ED-2, and ED-3. The blue light-emitting region PXA-B of the first light-emitting element ED-1, which emits blue light, may have the largest area, and the green light-emitting region PXA-G of the second light-emitting element ED-2, which emits green light, may have the smallest area. However, the disclosure is not limited thereto, and the light-emitting regions PXA-B, PXA-G, and PXA-R may emit light of colors other than blue light, green light, and red light. In another embodiment, the light-emitting regions PXA-B, PXA-G, and PXA-R may have a same area or may be provided in an area ratio different from that illustrated in FIG. 3.

Each of the light-emitting regions PXA-B, PXA-G, and PXA-R may be divided by the pixel defining film PDL. The peripheral regions NPXA may be regions between neighboring light-emitting regions PXA-B, PXA-G, and PXA-R and may correspond to the pixel defining films PDL. Each of the light-emitting regions PXA-B, PXA-G, and PXA-R may correspond to a pixel.

The pixel defining film PDL may define the light-emitting regions PXA-B, PXA-G, and PXA-R. The light-emitting regions PXA-B, PXA-G, and PXA-R and the peripheral region NPXA may be distinguished by the pixel defining film PDL.

Blue light-emitting regions PXA-B and red light-emitting regions PXA-R may be alternately arranged in the first direction axis DR1 to form a first group PXG1. The green light-emitting regions PXA-G may be arranged in the first direction axis DR1 to form a second group PXG2. The first group PXG1 may be disposed to be spaced apart from the second group PXG2 in the second direction axis DR2. Each of the first group PXG1 and the second group PXG2 may be provided in plurality. The first groups PXG1 and the second groups PXG2 may be alternately arranged in the second direction axis DR2.

A red light-emitting region PXA-R may be spaced apart from a green light-emitting region PXA-G in a fourth direction axis DR4. A blue light-emitting region PXA-B may be spaced apart from a green light-emitting region PXA-G in a fifth direction axis DR5. The fourth direction axis DR4 may be a direction between the first direction axis DR1 and the second direction axis DR2. The fifth direction axis DR5 may intersect the fourth direction axis DR4 and be inclined with respect to the second direction axis DR2.

The arrangement of the light-emitting regions PXA-B, PXA-G, and PXA-R is not limited to the arrangement illustrated in FIG. 3. For example, in the light-emitting regions PXA-B, PXA-G, and PXA-R, the blue light-emitting region PXA-B, the green light-emitting region PXA-G, and the red light-emitting region PXA-R may be sequentially and alternately arranged in the first direction axis DR1. The shapes of the light-emitting regions PXA-B, PXA-G, and PXA-R in a plan view are not limited to what is illustrated and may have shapes other than what is illustrated.

In FIG. 4, the base layer BS may include a single-layered or multi-layered structure. For example, the base layer BS may include a first synthetic resin layer, an intermediate layer with a multi-layered or single-layered structure, and a second synthetic resin layer, which are sequentially stacked. The intermediate layer may also be referred to as a base barrier layer. The intermediate layer may include, but is not particularly limited to, a silicon oxide (SiOₓ) layer and an amorphous silicon (a-Si) layer disposed on the silicon oxide layer. For example, the intermediate layer may include at least one of a silicon oxide layer, a silicon nitride layer, a silicon oxynitride layer, and an amorphous silicon layer.

Each of the first and second synthetic resin layers may include a polyimide-based resin. Each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a “˜˜”-based resin means to include a functional group of “˜˜”.

The circuit layer DP-CL may include a lower buffer layer BF disposed on the base layer BS, first to sixth insulating layers 10 to 60 disposed on the lower buffer layer BF, and multiple transistors TR. However, the stacked structure of the circuit layer DP-CL is limited to the embodiment in FIG. 4, and depending on the configuration of the pixel PX (see FIG. 1) and the process of the circuit layer DP-CL, the stacked structure of the circuit layer DP-CL may be partially changed.

The lower buffer layer BF may improve the bonding strength between the base layer BS and the semiconductor pattern or conductive pattern disposed on the lower buffer layer BF. A transistor TR may be disposed on the lower buffer layer BF. The transistor TR may be formed from the semiconductor pattern. The semiconductor pattern of the transistor TR may include polysilicon, amorphous silicon, or metal oxide, and as long as a material has a semiconductor property, it may be applied without limitation and the disclosure is not limited to one embodiment.

The transistor TR may include an active A-T, a source S-T, a drain D-T, and a gate G-T. The active A-T, the source S-T, and the drain D-T may be disposed on the lower buffer layer BF. The active A-T, the source S-T, and the drain D-T may be divided according to the doping concentration or conductivity of the semiconductor pattern. A region of the semiconductor pattern, which is doped with a dopant or in which metal oxide is reduced, may have high conductivity and may substantially serve as a source electrode and a drain electrode of the transistor TR. A region with high conductivity in the semiconductor pattern may correspond to the source S-T and drain D-T of the transistor TR. A region of the semiconductor pattern, which is undoped or doped at a low concentration or has low conductivity due to non-reduced metal oxide, may correspond to the active A-T (or channel) of the transistor TR.

The first insulating layer 10 may cover the semiconductor pattern of the transistor TR and be disposed on the lower buffer layer BF. The gate G-T of the transistor TR may be disposed on the first insulating layer 10. The gate G-T may overlap the active A-T of the transistor TR in a plan view. The gate G-T may function as a mask in a process of doping the semiconductor pattern of the transistor TR.

A second insulating layer 20 may be disposed on the gate G-T. A third insulating layer 30 may be disposed on the second insulating layer 20. A fourth insulating layer 40 may be disposed on the third insulating layer 30. A fifth insulating layer 50 may be disposed on the fourth insulating layer 40. A sixth insulating layer 60 may be disposed on the fifth insulating layer 50. Although not illustrated, the circuit layer DP-CL may further include a connection electrode, a contact hole, and the like for electrically connecting the transistors TR and the light-emitting elements ED-1, ED-2, and ED-3 to each other.

Each of the first to sixth insulating layers 10 to 60 may include an inorganic insulating layer or an organic insulating layer. For example, the inorganic insulating layer may include at least one of aluminum oxide, titanium oxide, silicon oxide, silicon oxynitride, zirconium oxide, and hafnium oxide. The organic insulating layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin.

The fifth insulating layer 50 may be a planarization layer. The fifth insulating layer 50 may be disposed directly below the uppermost insulating layer (for example, the sixth insulating layer 60) in the circuit layer DP-CL.

A lower surface 60_DF of the sixth insulating layer 60 disposed on the fifth insulating layer 50 may be flat. An upper surface 60_UF of the sixth insulating layer 60, which is spaced apart from the lower surface 60_DF of the sixth insulating layer 60, may not be flat. The sixth insulating layer 60 may be disposed directly below the light-emitting elements ED-1, ED-2, and ED-3.

The sixth insulating layer 60 may include a first region 60-A1 and a second region 60-A2 having different thicknesses. The first region 60-A1 and the second region 60-A2 may be integral with each other. A first thickness TN1 of the first region 60-A1 may be greater than a second thickness TN2 of the second region 60-A2. The first region 60-A1 may overlap the pixel defining film PDL in a plan view. The first region 60-A1 may overlap the peripheral region NPXA in a plan view. The second region 60-A2 may overlap the light-emitting regions PXA-B, PXA-G, and PXA-R in a plan view. The second region 60-A2 may overlap functional layers FL-1, FL-2, and FL-3 of the first to third light-emitting elements ED-1, ED-2, and ED-3 in a plan view, which will be described below. In this specification, the expression that one component overlaps another component is not limited to a case in which the two components have the same area and shape as each other and also includes a case in which they have different areas and/or different shapes.

An inorganic layer PN may be disposed on the sixth insulating layer 60. The inorganic layer PN may be directly disposed on the sixth insulating layer 60 and may be in contact with the sixth insulating layer 60. The inorganic layer PN may entirely overlap the first region 60-A1 of the sixth insulating layer 60 in a plan view. In a plan view (e.g., in the thickness direction DR3), the area of the inorganic layer PN may be greater than the area of the first region 60-A1 of the sixth insulating layer 60. The inorganic layer PN may overlap the peripheral region NPXA in a plan view. The inorganic layer PN may not overlap the light-emitting regions PXA-B, PXA-G, and PXA-R in a plan view. The inorganic layer PN may not overlap a pixel opening OH of the pixel defining film PDL in a plan view. The inorganic layer PN may have an inorganic opening OP. The inorganic opening OP of the inorganic layer PN may overlap the pixel opening OH of the pixel defining film PDL in a plan view. The inorganic layer PN may supply protons to the functional layers FL-1, FL-2, and FL-3. The functional layers FL-1, FL-2, and FL-3 may overlap the second region 60-A2 of the sixth insulating layer 60 in a plan view. The functional layers FL-1, FL-2, and FL-3 may not overlap the first region 60-A1 of the sixth insulating layer 60 in a plan view.

The inorganic layer PN disposed on the sixth insulating layer 60 including the first region 60-A1 and the second region 60-A2 having different thicknesses may more readily provide protons at sides of the functional layers FL-1, FL-2, and FL-3. Accordingly, the light-emitting efficiency of the first to third light-emitting elements ED-1, ED-2, and ED-3 according to an embodiment of the disclosure may be improved, and the display device DD may have excellent display efficiency. The inorganic layer PN will be described in more detail below.

The display element layer DP-EL may include an inorganic layer PN, a pixel defining film PDL, and first to third light-emitting elements ED-1, ED-2, and ED-3. The pixel defining film PDL may have a pixel opening OH. The pixel defining film PDL may separate the first to third light-emitting elements ED-1, ED-2, and ED-3.

The pixel defining film PDL may be formed of a polymer resin. For example, the pixel defining film PDL may include a polyacrylate-based resin or a polyimide-based resin. The pixel defining film PDL may include a light-absorbing material, or a black pigment or black dye. The pixel defining film PDL including a black pigment or black dye may implement a black pixel defining film. During the pixel defining film PDL is formed, carbon black or the like may be used as a black pigment or black dye, but the disclosure is not limited thereto.

Each of the first to third light-emitting elements ED-1, ED-2, and ED-3 may include a first electrode EL1, a second electrode EL2 disposed above the first electrode EL1, and a functional layer FL-1, FL-2, or FL-3 disposed between the first electrode EL1 and the second electrode EL2. Each of the first to third light-emitting elements ED-1, ED-2, and ED-3 may further include a capping layer CPL.

At least a portion of the first electrode EL1 may be exposed by the pixel opening OH of the pixel defining film PDL. At least a portion of the first electrode EL1 may be exposed by the inorganic opening OP of the inorganic layer PN. The first electrode EL1 may have conductivity. The first electrode EL1 may be formed of a metal material, a metal alloy, or a conductive compound. The first electrode EL1 may be a cathode or an anode. However, the disclosure is not limited thereto. The first electrode EL1 may be a pixel electrode. The first electrode EL1 may be a transmissive electrode, a semi-transmissive electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, a compound thereof, a mixture of thereof, and an oxide thereof.

In case that the first electrode EL1 is a transmissive electrode, the first electrode EL1 may be composed of a transparent metal oxide such as an indium tin oxide (ITO), an indium zinc oxide (IZO), a zinc oxide (ZnO), or an indium tin zinc oxide (ITZO). In case that the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). In another embodiment, the first electrode EL1 may have a multi-layered structure including a reflective film or semi-transmissive film formed of the above materials, and a transparent conductive film formed of an indium tin oxide (ITO), an indium zinc oxide (IZO), a zinc oxide (ZnO), an indium tin zinc oxide (ITZO), or the like. For example, the first electrode EL1 may have a three-layer structure of ITO/Ag/ITO, but the disclosure is not limited thereto. The first electrode EL1 may include an above-described metallic material, a combination of two or more metallic materials selected from among the above-described metallic materials, an oxide of the above-described metallic materials, or the like, and the disclosure is not limited thereto. The thickness of the first electrode EL1 may be in a range of about 700 Å to about 10000 Å. For example, the thickness of the first electrode EL1 may be in a range of about 1000 Å to about 3000 Å.

The second electrode EL2 may be a common electrode. The second electrode EL2 may be an anode or a cathode, but the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, and Zn, a compound thereof, a mixture thereof, and an oxide thereof.

The second electrode EL2 may be a transmissive electrode, a semi-transmissive electrode, or a reflective electrode. In case that the second electrode EL2 is a transmissive electrode, the second electrode EL2 may be composed of a transparent metal oxide such as an indium tin oxide (ITO), an indium zinc oxide (IZO), a zinc oxide (ZnO), or an indium tin zinc oxide (ITZO).

In case that the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). In another embodiment, the second electrode EL2 may have a multi-layered structure including a reflective film or semi-transmissive film formed of the above materials, and a transparent conductive film formed of an indium tin oxide (ITO), an indium zinc oxide (IZO), a zinc oxide (ZnO), an indium tin zinc oxide (ITZO), or the like. For example, the second electrode EL2 may include an above-described metallic material, a combination of two or more of the above-described metallic materials, an oxide of the above-described metallic materials, or the like.

Although not illustrated, the second electrode EL2 may be connected to an auxiliary electrode. In case that the second electrode EL2 is connected to the auxiliary electrode, the resistance of the second electrode EL2 may be reduced.

The functional layers FL-1, FL-2, and FL-3 may be disposed between the first electrode EL1 and the second electrode EL2. The functional layers FL-1, FL-2, and FL-3 of the first to third light-emitting elements ED-1, ED-2, and ED-3 may be disposed in the pixel opening OH so as to be separated from each other. The first light-emitting element ED-1 may include the first functional layer FL-1, the second light-emitting element ED-2 may include the second functional layer FL-2, and the third light-emitting element ED-3 may include the third functional layer FL-3.

The capping layer CPL may include an inorganic material or an organic material. For example, the capping layer CPL may include an inorganic material such as SiON, SiNₓ, SiO_{y}, an alkali metal compound such as LiF, an alkaline earth metal compound such as MgF₂, and the like.

For example, the capping layer CPL may include an organic material such as α-NPD, NPB, TPD, m-MTDATA, Alq₃, CuPc, TPD15 (N4, N4′-tetra (biphenyl-4-yl) biphenyl-4, 4′-diamine), TCTA (4, 4′, 4″-Tris (carbazol-9-yl)triphenylamine), and the like, or may include an epoxy resin or acrylate such as methacrylate.

The encapsulation layer TFE may include at least one inorganic film (hereinafter referred to as an inorganic encapsulation film). The encapsulation layer TFE may include at least one organic film (hereinafter referred to as an organic encapsulation film) and at least one inorganic encapsulation film.

The inorganic encapsulation film may protect the display element layer DP-EL from moisture/oxygen, and the organic encapsulation film may protect the display element layer DP-EL from foreign substances such as dust particles. The inorganic encapsulating film may include silicon nitride, silicon oxynitride, silicon oxide, titanium oxide, aluminum oxide, or the like, but the disclosure is not particularly limited thereto. The organic encapsulation film may include an acrylic-based compound, an epoxy-based compound, or the like. The organic encapsulation film may include a photopolymerizable organic material, but the disclosure is not particularly limited thereto.

The optical layer PP may include a base substrate BL and a color filter layer CFL. The base substrate BL may provide a base surface on which the color filter layer CFL is disposed. The base substrate BL may be a glass substrate, a metal substrate, or a plastic substrate. However, the disclosure is not limited thereto, and the base substrate BL may be an inorganic substrate, an organic substrate, or a composite material substrate.

The color filter layer CFL may include first to third filters CF-B, CF-G, and CF-R. The first to third filters CF-B, CF-G, and CF-R may be disposed to respectively correspond to the first to third light-emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed to respectively correspond to the first to third light-emitting regions PXA-B, PXA-G, and PXA-R.

Each of the first to third filters CF-B, CF-G, and CF-R may include a photosensitive polymer resin and a pigment or dye. The first filter CF-B may include a blue pigment or blue dye, the second filter CF-G may include a green pigment or green dye, and the third filter CF-R may include a red pigment or red dye. However, the disclosure is not limited thereto, and the first filter CF-B may not include a pigment or dye. The first filter CF-B may include a photosensitive polymer resin and may not include a pigment or dye. The first filter CF-B may be transparent. The first filter CF-B may be formed of a transparent photosensitive resin.

The color filter layer CFL may further include a buffer layer BFL. For example, the buffer layer BFL may be a protective layer that protects the first to third filters CF-B, CF-G, and CF-R. The buffer layer BFL may be an inorganic buffer layer including at least one inorganic material of silicon nitride, silicon oxide, and silicon oxynitride. The buffer layer BFL may be composed of a single layer or multiple layers.

The second filter CF-G and the third filter CF-R may be yellow filters. The second filter CF-G and the third filter CF-R may not be separated from each other and may be provided as an integral unit.

Although not illustrated, the color filter layer CFL may further include a light blocking portion (not illustrated). The light blocking portion may be a black matrix. The light blocking portion may include an organic light blocking material or an inorganic light blocking material which includes a black pigment or black dye. The light blocking portion may prevent a light leakage phenomenon and demarcate boundaries between adjacent filters CF-B, CF-G, and CF-R.

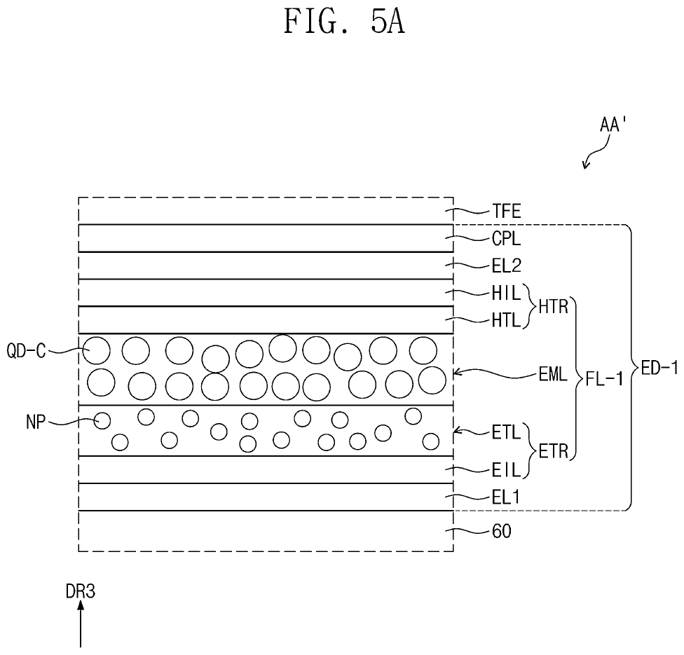

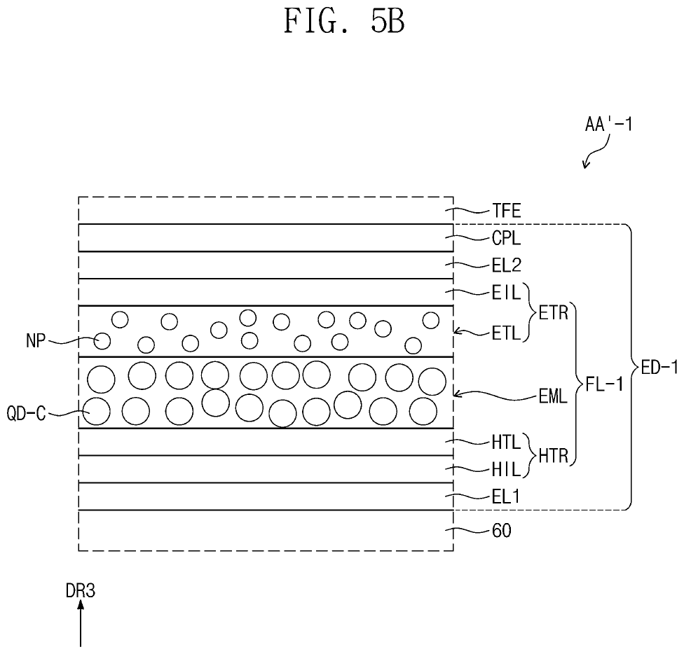

FIG. 5A is an enlarged schematic cross-sectional view of region AA′ in FIG. 4. FIG. 5B is a schematic cross-sectional view illustrating region AA′-1 which is another embodiment of the region AA′ of FIG. 4. The description of the first light-emitting element ED-1 with reference to FIGS. 5A and 5B may be equally applied to the second and third light-emitting elements ED-2 and ED-3 illustrated in FIG. 4.

Referring to FIGS. 5A and 5B, the functional layer FL-1 may include an electron transport region ETR, a light-emitting layer EML, and a hole transport region HTR. The electron transport region ETR may be spaced apart from the hole transport region HTR with the light-emitting layer EML interposed between the electron transport region ETR and the hole transport region HTR. The electron transport regions ETR of the first to third light-emitting elements ED-1, ED-2, and ED-3 (see FIG. 4) may be disposed in the pixel openings OH (see FIG. 4) so as to be separated from each other. The hole transport regions HTR of the first to third light-emitting elements ED-1, ED-2, and ED-3 (see FIG. 4) may be disposed in the pixel openings OH (see FIG. 4) so as to be separated from each other. The light-emitting layers EML of the first to third light-emitting elements ED-1, ED-2, and ED-3 (see FIG. 4) may be disposed in the pixel openings OH (see FIG. 4) defined in the pixel defining films PDL so as to be separated from each other.

FIGS. 5A and 5B are different from each other in the arrangement of the electron transport region ETR and the hole transport region HTR. FIG. 5A schematically illustrates that the electron transport region ETR, the light-emitting layer EML, and the hole transport region HTR are sequentially stacked on the first electrode EL1. On the other hand, FIG. 5B schematically illustrates that the hole transport region HTR, the light-emitting layer EML, and the electron transport region ETR are sequentially stacked on the first electrode EL1.

The hole transport region HTR may have a single layer made of a single material, a single layer made of different materials, or a multi-layered structure having multiple layers made of different materials. The thickness of the hole transport region HTR may be, for example, in a range of about 50 Å to about 15000 Å. For example, the thickness of the hole transport region HTR may be in a range of about 100 Å to about 10000 Å. For example, the thickness of the hole transport region HTR may be in a range of about 100 Å to about 5000 Å.

The hole transport region HTR may include a hole injection layer HIL and a hole transport layer HTL. Although not illustrated, the hole transport region HTR may further include an electron blocking layer (not illustrated). The hole injection layer HIL may be spaced apart from the light-emitting layer EML with the hole transport layer HTL interposed between the hole injection layer HIL and the light-emitting layer EML. FIG. 5A schematically illustrates that the hole transport layer HTL is disposed on the light-emitting layer EML and that the hole injection layer HIL is disposed on the hole transport layer HTL. On the other hand, FIG. 5B schematically illustrates that the hole injection layer HIL is disposed on the first electrode EL1 and that the hole transport layer HTL is disposed on the hole injection layer HIL.

The hole transport region HTR may include a hole injection material and/or a hole transport material. For example, the hole transport region HTR may include a phthalocyanine compound such as copper phthalocyanine, DNTPD(N1,N1′-([1,1′-biphenyl]-4,4′-diyl)bis(N1-phenyl-N4,N4-di-m-tolylbenzene-1,4-diamine)), m-MTDATA(4,4′,4″-[tris(3-methylphenyl)phenylamino]triphenylamine), TDATA(4,4′,4″-Tris(N,N-diphenylamino)triphenylamine), 2-TNATA(4,4′,4″-tris[N(2-naphthyl)-N-phenylamino]-triphenylamine), PEDOT/PSS (Poly(3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPB(N,N′-di(naphthalene-1-yl)-N,N′-diphenyl-benzidine), polyether ketone(TPAPEK) containing triphenylamine, 4-Isopropyl-4′-methyldiphenyliodonium[Tetrakis(pentafluorophenyl)borate], HATCN(dipyrazino [2,3-f: 2′, 3′-h]quinoxaline-2,3,6,7,10,11-hexacarbonitrile), etc.

The hole transport region HTR may include a carbazole-based derivative such as N-phenylcarbazole and polyvinylcarbazole, a fluorene-based derivative, TPD(N,N′-bis(3-methylphenyl)-N,N′-diphenyl-[1,1′-biphenyl]-4,4′-diamine), a triphenylamine-based derivative such as TCTA(4,4′,4″-tris(N-carbazolyl)triphenylamine), NPB(N,N′-di(naphthalene-1-yl)-N,N′-diplienyl-benzidine), TAPC(4,4′-Cyclohexylidene bis[N,N-bis(4-methylphenyl)benzenamine]), HMTPD(4,4′-Bis[N,N′-(3-tolyl)amino]-3,3′-dimethylbiphenyl), CzSi(9-(4-tert-Butylphenyl)-3,6-bis(triphenylsilyl)-9H-carbazole), CCP(9-phenyl-9H-3,9′-bicarbazole), mCP(1,3-Bis (N-carbazolyl) benzene), mDCP (1,3-bis(1,8-dimethyl-9H-carbazol-9-yl) benzene), or the like.

The light-emitting layer EML may include a quantum dot QD-C. The quantum dot QD-C may be provided in plurality and stacked to form layers. FIGS. 5A and 5B schematically illustrate that quantum dots QD-C having a circular cross-section as an embodiment are arranged to roughly form two layers, but the disclosure is not limited thereto. For example, the arrangement of the quantum dots QD-C may vary depending on the thickness of the light-emitting layer EML, the shape of the quantum dots QD-C included in the light-emitting layer EML, and the average diameter of the quantum dots QD-C. For example, in the light-emitting layer EML, the quantum dots QD-C may be aligned to be adjacent to each other to form one layer, or may be aligned to form multiple layers such as two or three layers.

The quantum dots QD-C may be crystals of a semiconductor compound. The quantum dots QD-C may emit light of light-emitting wavelengths depending on the sizes of the crystals. The diameter of the quantum dots QD-C may be, for example, in a range of about 1 nm to about 10 nm.

The quantum dots QD-C may be synthesized through a wet chemical process, a metal organic chemical vapor deposition (MOCVD) process, a molecular beam epitaxy (MBE) process, or a similar process. The wet chemical process is a method of growing quantum dot QD-C particle crystals after mixing an organic solvent and a precursor material. During the crystals grow, the organic solvent naturally may act as a dispersant coordinated on the surface of the quantum dot QD-C crystals and may control the growth of the crystals. Therefore, the wet chemical process may be more readily performed than vapor deposition methods such as the metal organic chemical vapor deposition (MOCVD) process or the molecular beam epitaxy (MBE) process and may control the growth of the quantum dot QD-C particles through a low-cost process.

The quantum dot QD-C may include a group II-VI semiconductor compound, a group I-II-VI semiconductor compound, a group II-IV-VI compound, a group J-JJ-IV-VI semiconductor compound, a group III-V semiconductor compound, a group III-VI semiconductor compound, a group I-III-VI semiconductor compound, a group IV-VI semiconductor compound, a group II-IV-V semiconductor compound, a group IV element or compound, or a combination thereof. In this specification, the term “group” refers to a group of the IUPAC periodic table.

Examples of the group II-VI semiconductor compound may include binary compounds such as CdS, CdSe, CdTe, ZnS, ZnSe, ZnTe, ZnO, HgS, HgSe, HgTe, MgSe, and MgS; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; quaternary compounds such as CdZnSeS, CdZnSeTe, CdZnSTe, CdHgSeS, CdHgSeTe, CdHgSTe, HgZnSeS, HgZnSeTe, and HgZnSTe; or a combination thereof.

The group II-VI semiconductor compound may further include a group I metal and/or a group IV element. The group I-II-VI compound may include CuSnS or CuZnS, and the Group II-IV-VI compound may include ZnSnS or the like. The group I-II-IV-VI compound may include quaternary compounds such as Cu₂ZnSnS₂, Cu₂ZnSnS₄, Cu₂ZnSnSe₄, Ag₂ZnSnS₂, and a mixture thereof.

Examples of the group III-V semiconductor compound may include binary compounds such as GaN, GaP, GaAs, GaSb, AlN, AlP, AlAs, AlSb, InN, InP, InAs, and InSb; ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb; quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; or a combination thereof. The group III-V semiconductor compound may further include a group II element. Examples of the group III-V semiconductor compounds further including the group II element may include InZnP, InGaZnP, InAlZnP, and the like.

Examples of the group III-VI semiconductor compound may include binary compounds such as GaS, Ga₂S₃, GaSe, Ga₂Se₃, GaTe, InS, InSe, In₂Se₃, and InTe; ternary compounds such as InGaS₃, and InGaSe₃; or a combination thereof.

Examples of the group I-III-VI semiconductor compound may include ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂; quaternary compounds such as AgInGaS₂ and AgInGaSe₂; or a combination thereof.

Examples of the group IV-VI semiconductor compound may include binary compounds such as SnS, SnSe, SnTe, PbS, PbSe, and PbTe; ternary compounds such as SnSeS, SnSeTe, SnSTe, PbSeS, PbSeTe, PbSTe, SnPbS, SnPbSe, and SnPbTe; quaternary compounds such as SnPbSSe, SnPbSeTe, and SnPbSTe; or a combination thereof.

Examples of the group II-IV-V semiconductor compound may be ternary compounds such as ZnSnP, ZnSnP₂, ZnSnAs₂, ZnGeP₂, ZnGeAs₂, CdSnP₂, CdGeP₂, and a mixture thereof.

The group IV element or compound may include elementary compounds such as Si and Ge; binary compounds such as SiC and SiGe; or a combination thereof.

Each element included in multi-element compounds, such as the binary compounds, the ternary compounds, and the quaternary compounds, may be present in a particle at a uniform or non-uniform concentration. For example, the above chemical formulas may indicate types of elements included in the compounds, and the ratios of elements in the compounds may be different from each other. For example, AgInGaS₂ may be AgInₓGa₁₋ₓS₂ (x is a real number between 0 and 1).

The quantum dot QD-C may have a single structure, in which the concentration of each element included in a corresponding quantum dot QD-C is uniform, or a dual core-shell structure. For example, a material included in a core and a material included in a shell may be different from each other.

The shell of the quantum dot QD-C may serve as a protective layer for maintaining semiconductor properties by preventing chemical modification of the core and/or as a charging layer for imparting electrophoretic properties to the quantum dot. The shell may have a single layer or multiple layers. The core/shell structure may have a concentration gradient in which the concentration of elements present in the shell decreases toward the core.

The shell of the quantum dot QD-C may include a metal or non-metal oxide, a semiconductor compound, or a combination thereof. Examples of the metal or non-metal oxide may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; ternary compounds such as MgAl₂O₄, CoFe₂O₄, NiFe₂O₄, and CoMn₂O₄; or a combination thereof. As described in this specification, examples of the semiconductor compound may include a group III-VI semiconductor compound; a group II-VI semiconductor compound; a group III-V semiconductor compound; a group III-VI semiconductor compound; a group I-III-VI semiconductor compound; a group IV-VI semiconductor compound; or a combination thereof. For example, the semiconductor compounds may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or a combination thereof.

Each element included in the multi-element compounds, such as the binary compounds, and the ternary compounds, may be present in a particle at a uniform or non-uniform concentration. For example, the above chemical formulas may indicate types of elements included in the compounds, and the ratios of elements in the compounds may be different from each other.

The quantum dot QD-C may have a full width of half maximum (FWHM) of a light-emitting wavelength spectrum of less than or equal to about 45 nm. For example, a full width of half maximum (FWHM) of a light-emitting wavelength spectrum of the quantum dots QD-C may be less than or equal to about 40 nm. For example, a full width of half maximum (FWHM) of a light-emitting wavelength spectrum of the quantum dots QD-C may be less than or equal to about 30 nm or less. Within those ranges, color purity or color reproducibility may be improved. Since light emitted through the quantum dot QD-C is emitted in all directions, a wide viewing angle may be improved. The shape of the quantum dot QD-C may be a spherical, pyramidal, multi-armed, cubic nanoparticle, nanotube, nanowire, nanofiber, or nanoplate particle.

Since an energy band gap may be controlled by adjusting the size of the quantum dot QD-C or the ratio of elements in a compound constituting the quantum dot QD-C, light of various wavelengths may be obtained from the light-emitting layer EML including the quantum dot QD-C. Therefore, by using the quantum dot QD-C described above (using quantum dots of different sizes or different element ratios in a quantum dot compound), the light-emitting elements ED-1, ED-2, and ED-3 (see FIG. 4) configured to emit light of various wavelengths may be implemented. For example, the control of the size of the quantum dot QD-C or the ratio of elements in a compound constituting the quantum dot QD-C may be selected so as to emit red light, green light, and/or blue light. The quantum dots QD-C may be configured to emit white light by combining light of various colors.

The quantum dot QD-C of the first light-emitting element ED-1 may emit blue light. The quantum dot QD-C of the second light-emitting element ED-2 (see FIG. 4) may emit green light. The quantum dot QD-C of the third light-emitting element ED-3 (see FIG. 4) may emit red light.

The diameters of the quantum dots QD-C in the first to third light-emitting elements ED-1, ED-2, and ED-3 may be different from each other. For example, the quantum dot QD-C of the first light-emitting element ED-1, which emits light in a relatively short-wavelength range, may have a smaller average diameter than the quantum dot QD-C of the second light-emitting element ED-2 (see FIG. 4) and the quantum dot QD-C of the third light-emitting element ED-3 (see FIG. 4), which emit light in a relatively long-wavelength range. The average diameter may be the arithmetic mean value of the particle diameters of multiple quantum dots. The particle diameter of the quantum dot may be the average value of the widths of the quantum dot particles on a cross section.

The electron transport region ETR may include an electron injection layer EIL and an electron transport layer ETL. Although not illustrated, the electron transport region ETR may further include a hole blocking layer (not illustrated). Unlike what is illustrated, the electron injection layer EIL may be omitted. The electron injection layer EIL may be spaced apart from the light-emitting layer EML with the electron transport layer ETL interposed between the electron injection layer EIL and the light-emitting layer EML. FIG. 5A schematically illustrates that the electron injection layer EIL is disposed on the first electrode EL1 and that the electron transport layer ETL is disposed on the electron injection layer EIL. In contrast, FIG. 5B schematically illustrates that the electron transport layer ETL is disposed on the light-emitting layer EML and that the electron injection layer EIL is disposed on the electron transport layer ETL.

The electron transport region ETR may include metal nanoparticles NP. At least one of the electron injection layer EIL and the electron transport layer ETL may include the metal nanoparticles NP. For example, the electron transport layer ETL may include the metal nanoparticles NP.

The metal nanoparticles NP may include a metal oxide. For example, the metal nanoparticles NP may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂, or a compound represented by Formula M-1 below. For example, the electron transport region ETR may include ZnO and/or ZnMgO.

Zn_{q}Me_{(1-q)}O [Formula M-1]

In Formula M-1 above, q may be between 0 and 0.5. Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

The electron transport region ETR may further include an electron injection material and/or an electron transport material. For example, the electron transport region ETR may include an anthracene-based compound. In another embodiment, the electron transport region ETR may include, for example, Alq3(Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9, 10-dinaphthylanthracene, TPBi(1,3,5-Tri(1-phenyl-1H-benzo[d]imidazol-2-yl)benzene), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,08)-(1,1′-Biphenyl-4-olato)aluminum), Bebg2(berylliumbis(benzoquinolin-10-olate)), ADN(9,10-di(naphthalene-2-yl) anthracene), BmPyPhB(1,3-Bis [3,5-di (pyridin-3-yl) phenyl]benzene), and mixtures thereof. In another embodiment, the electron transport region ETR may include BCP (2,9-dimethyl-4,7-diphenyl-1,10-phenanthroline), TSPO1 (diphenyl(4-(triphenylsilyl)phenyl)phosphine oxide), Bphen(4,7-diphenyl-1,10-phenanthroline), etc.

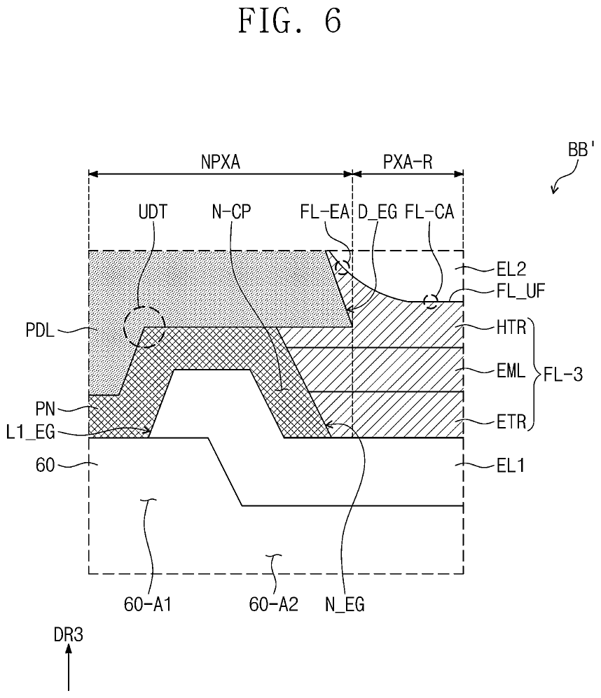

FIG. 6 is an enlarged schematic cross-sectional view of region BB′ in FIG. 4. Referring to FIG. 6, a second edge N_EG of the inorganic layer PN may be disposed inside a first edge D_EG of the pixel defining film PDL. The second edge N_EG of the inorganic layer PN may overlap the pixel defining film PDL in a plan view. The second edge N_EG of the inorganic layer PN may define the inorganic opening OP (see FIG. 4). The first edge D_EG of the pixel defining film PDL may define the pixel opening OH (see FIG. 4). The pixel defining film PDL may include an undercut portion UDT.

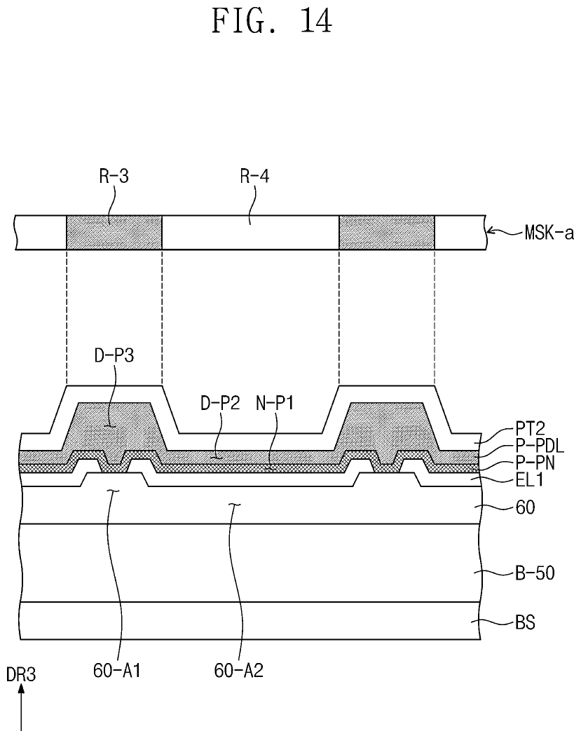

In a method of manufacturing a display device according to an embodiment of the disclosure, which will be described below, the inorganic layer PN may be formed from a preliminary inorganic layer P-PN (see FIG. 14), and the pixel defining film PDL may be formed from a preliminary pixel defining film P-PDL (see FIG. 14). The inorganic layer PN may be formed by removing a first portion N-P1 (see FIG. 14) of the preliminary inorganic layer P-PN (see FIG. 14). The pixel defining film PDL may be formed by removing a second portion D-P2 (see FIG. 14) of the preliminary pixel defining film P-PDL (see FIG. 14). The first portion N-P1 (see FIG. 14) of the preliminary inorganic layer P-PN (see FIG. 14) and the second portion D-P2 (see FIG. 14) of the preliminary pixel defining film P-PDL (see FIG. 14) may be removed in a same process operation. Accordingly, the second edge N_EG of the inorganic layer PN may be formed to be disposed more inward than the first edge D_EG of the pixel defining film PDL, and the pixel defining film PDL may be formed to include the undercut portion UDT. As the first portion N-P1 (see FIG. 14) of the preliminary inorganic layer P-PN (see FIG. 14) and the second portion D-P2 (see FIG. 14) of the preliminary pixel defining film P-PDL (see FIG. 14) are removed in a same process operation, the method of manufacturing the display device according to an embodiment of the disclosure, which will be described below, may have excellent manufacturing efficiency.

The inorganic layer PN may include at least one of amorphous silicon, silicon nitride, silicon oxide, and silicon oxynitride. The amorphous silicon, the silicon nitride, the silicon oxide, and the silicon oxynitride may include a large amount of protons. Accordingly, the inorganic layer PN may supply protons to the electron transport region ETR. As described above, the electron transport region ETR may include the metal nanoparticles NP (see FIGS. 5A and 5B) composed of a metal oxide.

The metal nanoparticles composed of metal oxide may include defects on the surfaces. As electrons are trapped in the defects on the surfaces, the electrons may not be supplied to the light-emitting layer, and therefore, deterioration or the like of the light-emitting element may occur. During positive aging is performed to eliminate the defects on the surfaces of the metal nanoparticles, the components (for example, light-emitting elements) of the display device may not be manufactured uniformly and the protons may not be supplied uniformly, thereby resulting in differences. In contrast, in an embodiment of the disclosure, the inorganic layer PN may eliminate defects in the metal nanoparticles NP by supplying protons to the electron transport region ETR. Accordingly, electrons may be readily supplied from the electron transport region ETR to the light-emitting layer EML, and therefore, the light-emitting elements ED-1, ED-2, and ED-3 (see FIG. 4) may have excellent efficiency. By including the inorganic layer PN, the display device DD (see FIG. 4) according to an embodiment of the disclosure may have excellent display efficiency.

Referring to FIG. 6, the inorganic layer PN may contact the electron transport region ETR in a direction perpendicular to the thickness direction DR3. The inorganic layer PN may include a portion N-CP inclined with respect to the thickness direction DR3. The inclined portion N-CP of the inorganic layer PN may be a portion disposed on the first electrode EL1. The inclined portion N-CP of the inorganic layer PN may contact the electron transport region ETR. The inorganic layer PN including the inclined portion N-CP in contact with the electron transport region ETR may supply protons to the electron transport region ETR. Accordingly, the display device DD (see FIG. 4) according to an embodiment of the disclosure may have excellent display efficiency.

The inorganic layer PN may cover a third edge L1_EG of the first electrode EL1. The third edge L1_EG of the first electrode EL1 may be disposed on the first region 60-A1 having a relatively large first thickness TN1 (see FIG. 4) in the sixth insulating layer 60. The third edge L1_EG of the first electrode EL1 may be inclined with respect to the thickness direction DR3.

In the thickness direction DR3, the first electrode EL1 may be spaced apart from the pixel defining film PDL with the inorganic layer PN interposed between the first electrode EL1 and the pixel defining film PDL. In another direction perpendicular to the thickness direction DR3, the first electrode EL1 may be spaced apart from the pixel defining film PDL with the inorganic layer PN interposed between the first electrode EL1 and the pixel defining film PDL. Since the inorganic layer PN may be disposed to cover the third edge L1_EG of the first electrode EL1, the first electrode EL1 and the pixel defining film PDL may be spaced apart from each other.

The pixel defining film PDL may be spaced apart from the sixth insulating layer 60 with the inorganic layer PN interposed between the pixel defining film PDL and the sixth insulating layer 60. The inorganic layer PN may be directly disposed on the sixth insulating layer 60, which is the uppermost insulating layer of the circuit layer DP-CL, and the pixel defining film PDL may be spaced apart from the uppermost insulating layer (for example, the sixth insulating layer 60) of the circuit layer DP-CL.

On an upper surface FL_UF of the third functional layer FL-3, an edge region FL-EA may be disposed higher than a central region FL-CA. The edge region FL-EA of the third functional layer FL-3 may contact the pixel defining film PDL. Due to a surface tension between the third functional layer FL-3 and the pixel defining film PDL, the edge region FL-EA in the third functional layer FL-3 may be disposed higher than the central region FL-CA. Although the third functional layer FL-3 is described as an example in FIG. 6, the same description may be applied to the edge regions of the first and second functional layers FL-1 and FL-2 illustrated in FIG. 4.

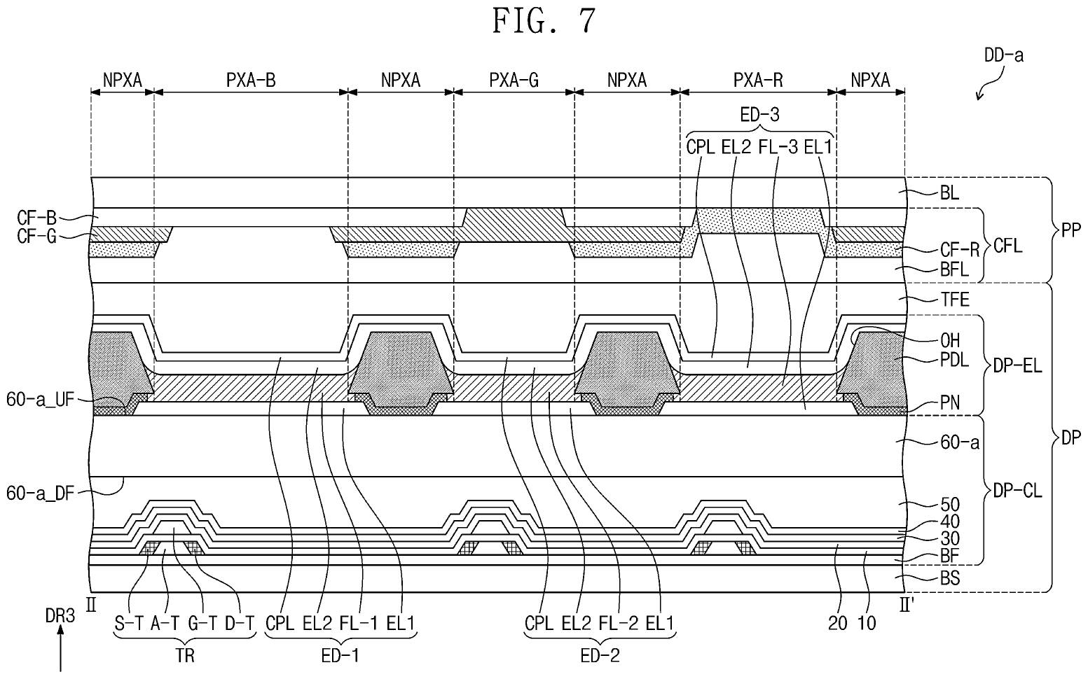

FIG. 7 is a schematic cross-sectional view illustrating a display device DD-a according to another embodiment of the disclosure. Compared to the display device DD illustrated in FIG. 4, the display device DD-a illustrated in FIG. 7 differs in a sixth insulating layer 60-a. Hereinafter, in the description of FIG. 7, the contents overlapping the contents described with reference to FIGS. 1 to 6 will not be described again and differences will be described.

Referring to FIG. 7, a lower surface 60-a_DF of the sixth insulating layer 60-a may be flat. An upper surface 60-a_UF of the sixth insulating layer 60-a may be flat.

The inorganic layer PN may be disposed to cover the third edge L1_EG (see FIG. 6) of the first electrode EL1 inclined with respect to the thickness direction DR3. The inorganic layer PN may contact the first to third functional layers FL-1, FL-2, and FL-3 in a direction perpendicular to the thickness direction DR3. For example, the inorganic layer PN may contact the electron transport region ETR (see FIG. 6) in a direction perpendicular to the thickness direction DR3.

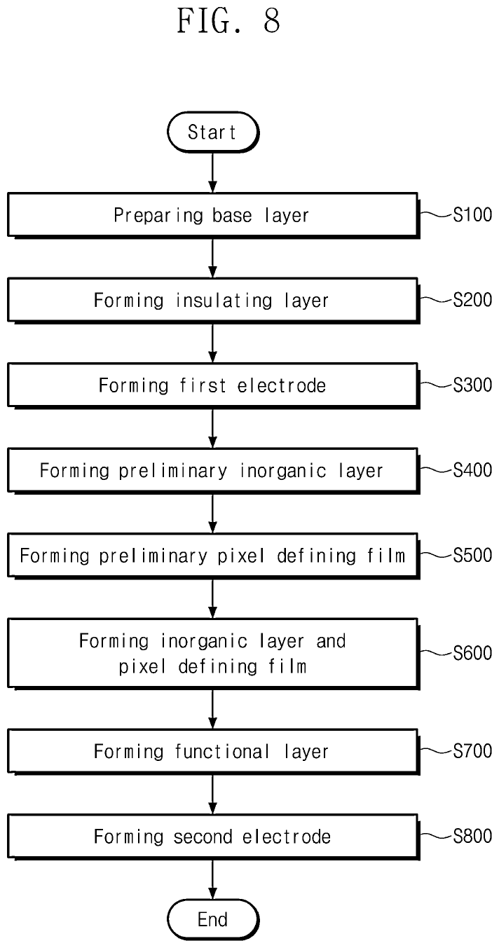

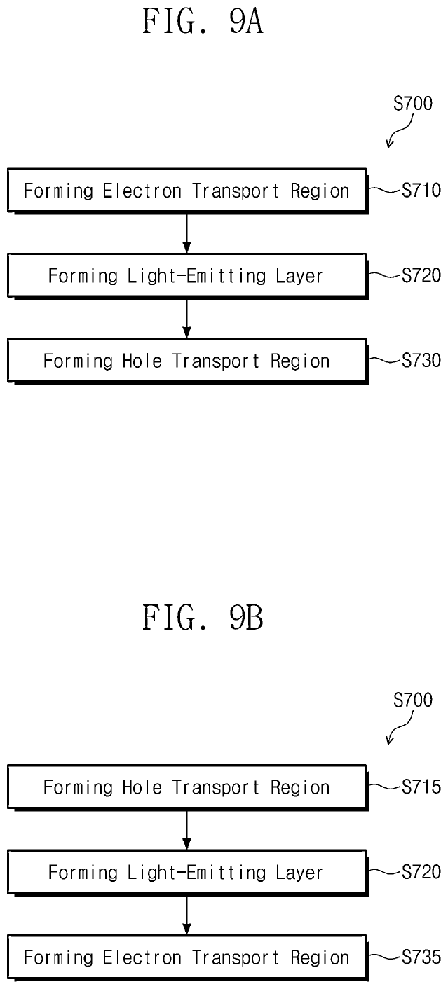

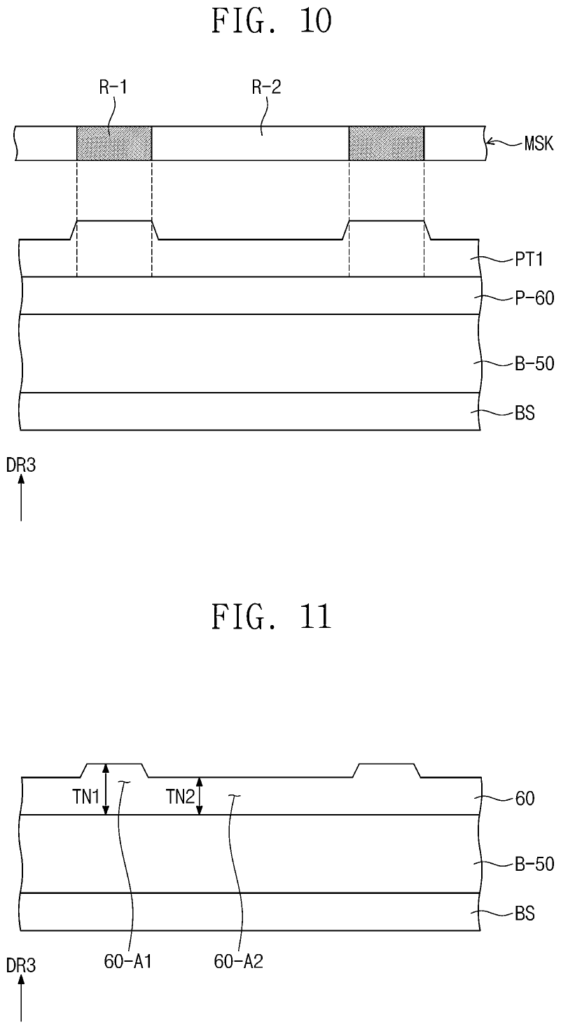

The display device according to an embodiment of the disclosure may be manufactured by a method of manufacturing a display device according to an embodiment of the disclosure. FIGS. 8, 9A, and 9B are flowcharts showing the method of manufacturing the display device according to an embodiment of the disclosure. FIGS. 10 to 17 schematically illustrate steps of manufacturing the display device according to an embodiment of the disclosure. Hereinafter, in the description of FIGS. 8 to 17, the contents overlapping the contents described with reference to FIGS. 1 to 7 will not be described again and differences will be described.

Referring to FIG. 8, the method of manufacturing the display device according to an embodiment of the disclosure may include preparing a base layer (S100), forming an insulating layer (S200), forming a first electrode (S300), forming a preliminary inorganic layer (S400), forming a preliminary pixel defining film (S500), forming an inorganic layer and a pixel defining film (S600), forming a functional layer (S700), and forming a second electrode (S800). Referring to FIGS. 9A and 9B, the forming of the functional layer (S700) may include forming an electron transport region (S710, S735), forming a light-emitting layer (S720), and forming a hole transport region (S730, S715). One of the forming of the electron transport region (S710, S735) and the forming of the hole transport region (S730, S715) may be performed before the forming of the light-emitting layer (S720), and another one thereof may be performed after the forming of the light-emitting layer (S720). Referring to FIG. 9A, the forming of an electron transport region (S710) may be performed before the forming of the light-emitting layer (S720), and the forming of the hole transport region (S730) may be performed after the forming of the light-emitting layer (S720). In contrast, referring to FIG. 9B, the forming of the hole transport region (S715) may be performed before the forming of the light-emitting layer (S720), and the forming of the electron transport region (S735) may be performed after the forming of the light-emitting layer (S720).

FIGS. 10 and 11 schematically illustrate a step of forming a sixth insulating layer 60 from a preliminary sixth insulating layer P-60. Referring to FIG. 10, the sixth preliminary insulating layer P-60 may be formed on the base layer BS. For example, a lower layer B-50 may be formed on the base layer BS, and the preliminary sixth insulating layer P-60 may be formed on the lower layer B-50. The lower layer B-50 may correspond to components (i.e., the transistor TR, the lower buffer layer BF, and the first to fifth insulating layers 10 to 50) excluding the sixth insulating layer 60 among the components of the circuit layer DP-CL illustrated in FIG. 4.

The preliminary sixth insulating layer P-60 may include an organic material. However, the disclosure is not limited thereto, and the preliminary sixth insulating layer P-60 may include an inorganic material.

On the preliminary sixth insulating layer P-60, a first photosensitive film pattern PT1 may be formed and a first mask MSK may be provided. The sixth insulating layer 60 (see FIG. 11) including first and second regions 60-A1 and 60-A2 (see FIG. 11) having different thicknesses may be formed from the preliminary sixth insulating layer P-60. A first thickness TN1 (see FIG. 11) of the first region 60-A1 (see FIG. 11) may be greater than a second thickness TN2 (see FIG. 11) of the second region 60-A2 (see FIG. 11). The first mask MSK may include a first mask region R-1 and a second mask region R-2 having different transmittances for irradiated light. The first mask MSK may be a half tone mask. Accordingly, the sixth insulating layer 60 (see FIG. 11) including the first and second regions 60-A1 and 60-A2 (see FIG. 11) having different thicknesses may be formed. Unlike what is illustrated, in case that the half tone mask is not provided on the preliminary sixth insulating layer P-60, the sixth insulating layer 60-a illustrated in FIG. 7 may be formed.

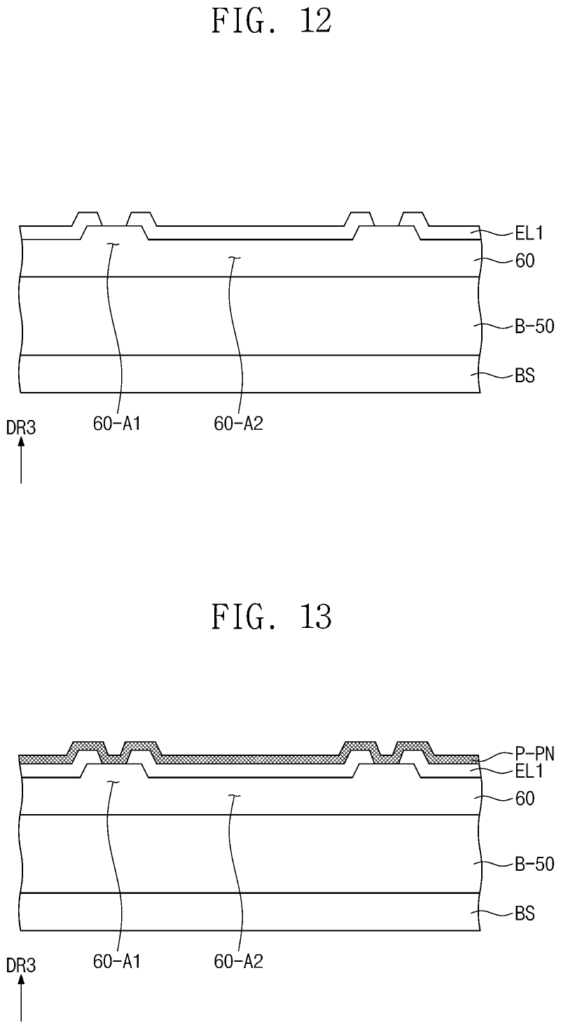

Referring to FIG. 12, the first electrode EL1 may be formed on the sixth insulating layer 60. The first electrode EL1 may be formed of a metal material, a metal alloy, or a conductive compound.

Referring to FIG. 13, a preliminary inorganic layer P-PN may be formed on the first electrode EL1. The preliminary inorganic layer P-PN may be formed to entirely overlap the first and second regions 60-A1 and 60-A2 of the sixth insulating layer 60 in a plan view. For example, the preliminary inorganic layer P-PN may include a silicon-based gas and a nitrogen-based gas. The preliminary inorganic layer P-PN may include at least one of amorphous silicon, silicon nitride, silicon oxide, and silicon oxynitride. The preliminary inorganic layer P-PN may be formed by a plasma enhanced chemical vapor deposition (PECVD) method. The inorganic layer PN formed from the preliminary inorganic layer P-PN may include at least one of amorphous silicon, silicon nitride, silicon oxide, and silicon oxynitride.

Referring to FIG. 14, a preliminary pixel defining film P-PDL may be formed on the preliminary inorganic layer P-PN. The preliminary pixel defining film P-PDL may be formed to entirely overlap the first and second regions 60-A1 and 60-A2 of the sixth insulating layer 60 in a plan view. After providing a material for forming the preliminary pixel defining film P-PDL on the preliminary inorganic layer P-PN, a second photosensitive film pattern PT2 may be formed and a second mask MSK-a may be provided. The second mask MSK-a may include third and fourth mask regions R-3 and R-4 having different light transmittances. The second mask MSK-a may be a halftone mask. Accordingly, the preliminary pixel defining film P-PDL including second and third portions D-P2 and D-P3 having different thicknesses may be formed. The second portion D-P2 of the preliminary pixel defining film P-PDL may overlap the second region 60-A2 of the sixth insulating layer 60 in a plan view. The third portion D-P3 of the preliminary pixel defining film P-PDL may overlap the first region 60-A1 of the sixth insulating layer 60 in a plan view.

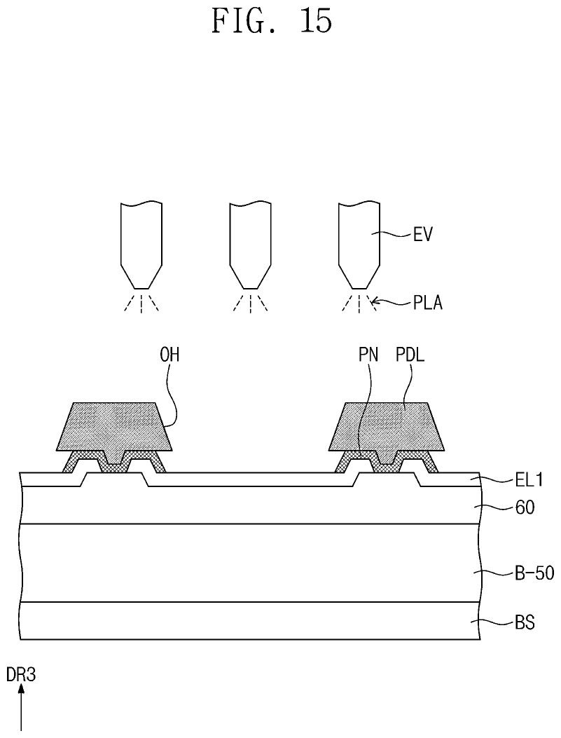

The first portion N-P1 of the preliminary inorganic layer P-PN may overlap the second region 60-A2 of the sixth insulating layer 60 in a plan view. The inorganic layer PN and the pixel defining film PDL illustrated in FIG. 15 may be formed by removing the first portion N-P1 of the preliminary inorganic layer P-PN and the second portion D-P2 of the preliminary pixel defining film P-PDL. The second portion D-P2 of the preliminary pixel defining film P-PDL may overlap the first portion N-P1 of the preliminary inorganic layer P-PN in a plan view. The pixel defining film PDL may be formed from the third portion D-P3 of the preliminary pixel defining film P-PDL.

The first portion N-P1 of the preliminary inorganic layer P-PN and the second portion D-P2 of the preliminary pixel defining film P-PDL may be removed in a same process operation. Accordingly, the second edge N_EG (see FIG. 6) of the inorganic layer PN may be formed to be disposed more inward than the first edge D_EG (see FIG. 6) of the pixel defining film PDL. The pixel defining film PDL may include an undercut portion UDT (see FIG. 6).

The first portion N-P1 of the preliminary inorganic layer P-PN and the second portion D-P2 of the preliminary pixel defining film P-PDL may be removed through an ashing process. After the second portion D-P2 is removed, the pixel defining film PDL having a pixel opening OH (see FIG. 15) may be formed. The first electrode EL1 may be exposed by the pixel opening OH of the pixel defining film PDL.

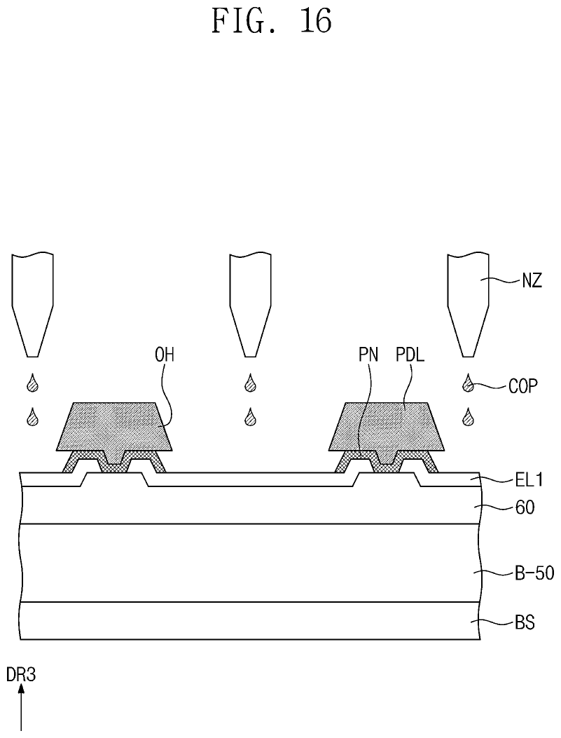

Referring to FIGS. 15 and 16, plasma treatment may be performed on the pixel defining film PDL before providing a composition COP. The performing of the plasma treatment may be to impart liquid-repellent properties to the pixel defining film PDL by providing a gas PLA to the pixel defining film PDL through a plasma device EV. The gas PLA may be a fluorine-containing gas. The fluorine-containing gas may include at least one of CF₄, C₃F₆, C₄F₈, SF₆, CHF₃, C₅F₈, CH₂F₂, C₂HF₅, CH₃F, and NF₃. For example, the fluorine-containing gas may include at least one of CF₄ or NF₃.

As the pixel defining film PDL has liquid-repellent properties, the composition COP may be dividedly provided in the pixel opening OH, and the functional layer FL may be dividedly formed. Accordingly, as illustrated in FIGS. 4 and 7, the first to third functional layers FL-1, FL-2, and FL-3 may be dividedly formed in the pixel opening OH.

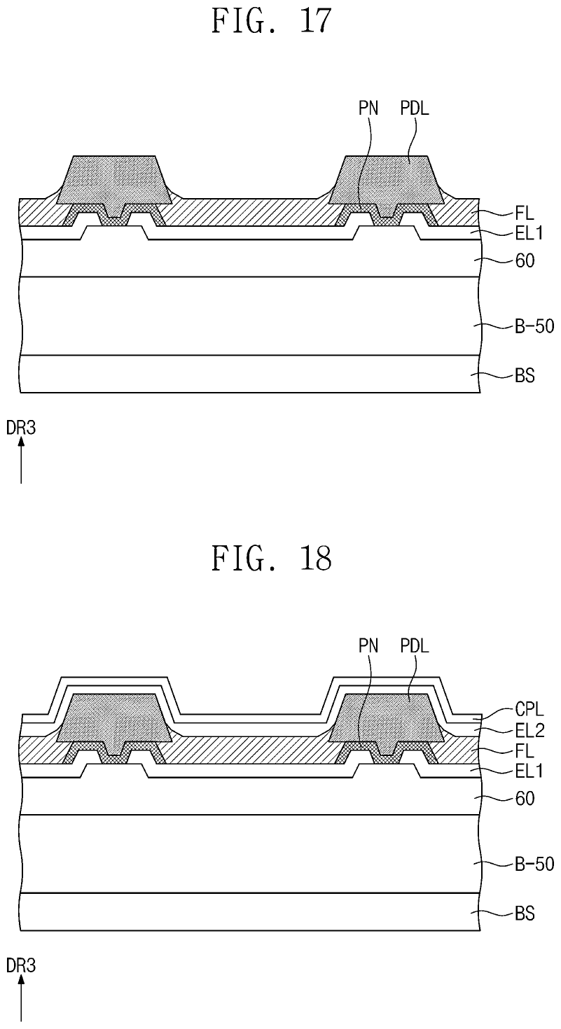

Referring to FIG. 16, the composition COP may be provided on the first electrode EL1. Referring to FIGS. 16 and 17, at least a portion of the functional layer FL may be formed from the composition COP. The functional layer FL may be formed on the first electrode EL1.

The functional layer FL may include an electron transport region ETR, a light-emitting layer EML, and a hole transport region HTR described with reference to FIGS. 5A and 5B. The functional layer FL may correspond to the first to third functional layers FL-1, FL-2, and FL-3 illustrated in FIGS. 4 and 7.

The electron transport region ETR and the light-emitting layer EML may be formed by providing the composition COP. A first composition COP for forming the light-emitting layer EML may include quantum dots QD-C(see FIGS. 5A and 5B). The first composition COP may further include a first solvent in which the quantum dots QD-C(see FIGS. 5A and 5B) are readily dispersed.

A second composition COP for forming the electron transport region ETR may include metal nanoparticles NP (see FIGS. 5A and 5B). The second composition COP for forming the electron transport region ETR may further include a second solvent in which metal nanoparticles NP (see FIGS. 5A and 5B) are readily dispersed. Since the method of providing the first composition for forming the light-emitting layer EML and the method of providing the second composition for forming the electron transport region ETR are the same as each other, the same reference numerals are used for the first and second compositions.

Each of the compositions COP for forming the light-emitting layer EML and the electron transport region ETR may be provided by an inkjet printing or dispensing method. Although FIG. 16 schematically illustrates that the composition COP is provided through a nozzle NZ, a device for providing the composition COP is not limited thereto.

Referring to FIG. 18, a second electrode EL2 may be formed on the functional layer FL. A capping layer CPL may be formed on the second electrode EL2. For example, the second electrode EL2 may include a metal material, a metal alloy, or a conductive compound. The capping layer CPL may include an organic material or an inorganic material.

The method of manufacturing the display device according to an embodiment of the disclosure may include forming an inorganic layer and a pixel defining film by removing the first portion of the preliminary inorganic layer and the second portion of the preliminary pixel defining film. As the first portion of the preliminary inorganic layer and the second portion of the preliminary pixel defining film are removed in a same process operation, the method of manufacturing the display device according to an embodiment of the disclosure may have excellent manufacturing efficiency.

A display device according to an embodiment of the disclosure may be manufactured by a method of manufacturing the display device according to an embodiment of the disclosure. The display device according to an embodiment of the disclosure may include a display element layer disposed on an insulating layer. The display element layer may include an inorganic layer, a pixel defining film, and a light-emitting element. A second edge of the inorganic layer may be disposed more inward than a first edge of the pixel defining film. The inorganic layer may supply protons to the electron transport region of the light-emitting element. Accordingly, the light efficiency of the light-emitting element may be improved, and the display device according to an embodiment of the disclosure may exhibit excellent display efficiency.

The display device according to an embodiment of the disclosure may exhibit excellent display efficiency by including an inorganic layer that supplies protons.

The method of manufacturing the display device according to an embodiment of the disclosure may exhibit excellent manufacturing efficiency by forming an inorganic layer and a pixel defining film in a same process operation.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer;
an insulating layer disposed on the base layer;
a pixel defining film disposed on the insulating layer and having a pixel opening;
a light-emitting element disposed on the insulating layer; and
an inorganic layer disposed on the insulating layer and including an edge which is disposed more inward than an edge of the pixel defining film and overlaps the pixel defining film in a plan view,
wherein the light-emitting element comprises:
a first electrode exposed by the pixel opening;
a second electrode disposed on the first electrode;
a light-emitting layer including quantum dots and disposed between the first electrode and the second electrode;
a hole transport region disposed between the first electrode and the second electrode; and
an electron transport region including a metal oxide, spaced apart from the hole transport region with the light-emitting layer interposed between the electron transport region and the hole transport region, and disposed between the first electrode and the second electrode.

2. The display device of claim 1, wherein the inorganic layer comprises at least one of amorphous silicon, silicon nitride, silicon oxide, and silicon oxynitride.

3. The display device of claim 1, wherein, in a direction perpendicular to a thickness direction of the display device, the inorganic layer is in contact with the electron transport region.

4. The display device of claim 1, wherein the inorganic layer does not overlap the pixel opening in a plan view.

5. The display device of claim 1, wherein the inorganic layer covers an edge of the first electrode.

6. The display device of claim 1, wherein the inorganic layer is in contact with the insulating layer.

7. The display device of claim 1, wherein
an inorganic opening is defined in the inorganic layer, and
the inorganic opening overlaps the pixel opening in a plan view.

8. The display device of claim 1, wherein the first electrode is spaced apart from the pixel defining film with the inorganic layer interposed between the first electrode and the pixel defining film.

9. The display device of claim 1, wherein the pixel defining film is spaced apart from the insulating layer with the inorganic layer interposed between the pixel defining film and the insulating layer.

10. The display device of claim 1, wherein the insulating layer comprises:
a first region that overlaps the pixel defining film in a plan view and has a first thickness; and
a second region that overlaps the pixel opening in a plan view and has a second thickness smaller than the first thickness.

11. The display device of claim 10, wherein the inorganic layer entirely overlaps the first region in a plan view.

12. The display device of claim 1, wherein the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, or TiO₂, and a compound represented by Formula M-1 below:
Zn_{q}Me_{(1-q)}O [Formula M-1]
wherein in Formula M-1,
q is a rational number between 0 and 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

13. A method for manufacturing a display device, the method comprising:
preparing a base layer;
forming an insulating layer on the base layer;
forming a first electrode on the insulating layer;
forming a preliminary inorganic layer on the first electrode;
forming a preliminary pixel defining film on the preliminary inorganic layer by using a first halftone mask;
forming an inorganic layer and a pixel defining film having a pixel opening by removing a first portion of the preliminary inorganic layer and a second portion of the preliminary pixel defining film overlapping the first portion in a plan view;
forming a functional layer on the first electrode exposed by the pixel opening; and
forming a second electrode on the functional layer, wherein
the forming of the functional layer comprises:
forming a light-emitting layer by providing a first composition including quantum dots;
forming a hole transport region; and
forming an electron transport region by providing a second composition including a metal oxide,
one of the forming of the hole transport region and the forming of the electron transport region is performed before the forming of the light-emitting layer, and
another one of the forming of the hole transport region and the forming of the electron transport region is performed after the forming of the light-emitting layer.

14. The method of claim 13, wherein, in the forming of the inorganic layer and the pixel defining film, an edge of the inorganic layer is disposed more inward than an edge of the pixel defining film.

15. The method of claim 13, wherein the first portion of the preliminary inorganic layer and the second portion of the preliminary pixel defining film are removed through an ashing process.

16. The method of claim 13, wherein the insulating layer is formed to include a first region having a first thickness and a second region having a second thickness smaller than the first thickness by using a second halftone mask.

17. The method of claim 13, wherein each of the first portion of the preliminary inorganic layer and the second portion of the preliminary pixel defining film overlaps the second region of the insulating layer in a plan view.

18. The method of claim 13, wherein the inorganic layer comprises at least one of amorphous silicon, silicon nitride, silicon oxide, and silicon oxynitride.

19. The method of claim 13, wherein each of the first composition and the second composition is provided by an inkjet printing method or a dispensing method.

20. The method of claim 13, further comprising:
performing plasma treatment by providing a fluorine-containing gas to the pixel defining film before the forming of the light-emitting layer, the hole transport region, and the electron transport region,
wherein the fluorine-containing gas comprises at least one of CF₄, C₃F₆, C₄F₈, SF₆, CHF₃, C₅F₈, CH₂F₂, C₂HF₅, CH₃F, and NF₃.
